(19) United States
(12) Patent Application Publication
(10) Pub. No.: US 2017/0140971 A1
(43) Pub. Date: May 18, 2017

(54) ADHESIVE WITH TUNABLE ADHESION FOR HANDLING ULTRA-THIN WAFER

(71) Applicants: NACHIKET R. RARAVIKAR, Gilbert, AZ (US); MOHIT MAMODIA, Chandler, AZ (US)

(72) Inventors: NACHIKET R. RARAVIKAR, Gilbert, AZ (US); MOHIT MAMODIA, Chandler, AZ (US)

(21) Appl. No.: 14/941,585

(22) Filed: Nov. 14, 2015

(51) Int. Cl. H01L 21/683; H01L 21/67; H01L 21/673

(52) U.S. Cl. CPC H01L 21/6836; H01L 21/67346; H01L 21/67132; H01L 21/67109; H01L 21/6838

(57) ABSTRACT

Described is an apparatus which comprises a wafer tray having an adhesive layer, with dynamically adjustable adhesion properties, deposited on a surface of the wafer tray; a wafer positioned on the wafer tray; and a cooling agent which is operable to cool at least a portion of the adhesive layer below its glass transition temperature (T_{g}) such that the wafer can be lifted off the wafer tray. Described is an apparatus which comprises: a tape having an adhesive layer, the adhesive layer having dynamically adjustable adhesion properties; a chip package to be attached to the tape via the adhesive layer; and a cooling agent which is operable to cool at least a portion of the adhesive layer below its T_{g} such that the chip package can be lifted off the tape.

### BACKGROUND

Handling ultra-thin silicon wafers during die preparation stages and throughout the assembly process is challenging. An ultra-thin silicon wafer may have dies of integrated circuits fabricated on them or may be just a slice of substrate. An ultra-thin silicon wafer (e.g., a wafer of 25 μm thickness or less) is fragile and can break or its backend structures may get damaged during handling. Current solutions for handling wafers involve various tape-and-reel or adhesive media.

Conventional tape-and-reel solutions for wafer handling do not work for handling ultra-thin silicon wafers because wafers are free to move inside a tape, and even a simple movement may damage either the silicon itself or its backend. Also, a thin wafer can easily move from one pocket to another pocket resulting in yield loss. The adhesive media helps to hold the wafer (and hence its dies) in place, however, it becomes difficult to release the ultra-thin silicon wafer (e.g., less than 50 μm thickness) from such adhesives without causing damage to the wafer. Currently, there are no known media solutions to handle ultra-thin die(s) through the assembly process.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a top view and a side view of a wafer tray processed with adhesive having tunable adhesion, the wafer tray having one or more wafers, in accordance with some embodiments of the disclosure.

FIGS. 2A-B illustrate side views of the wafer tray of FIG. 1 with apparatus to cool the adhesive for picking up the wafers off the wafer tray, according to some embodiments of the disclosure.

FIGS. 3A-B illustrate side views of the wafer tray of FIG. 1 with apparatus to locally cool a portion of the adhesive for picking up one wafer off the wafer tray, according to some embodiments of the disclosure.

FIGS. 4A-B illustrate side views of the wafer tray of FIG. 1 with apparatus to locally cool a portion of the adhesive for picking up one die from a wafer off the wafer tray, according to some embodiments of the disclosure.

FIG. 5 illustrates a flowchart of a method for handling ultra-thin wafer(s), according to some embodiments of the disclosure.

FIG. 6 illustrates a system having a machine-readable storage media having instructions stored thereon to perform one or more operations of the flowchart of FIG. 5, in accordance with some embodiments of the disclosure.

FIG. 7 illustrates a smart device or a computer system or a SoC (System-on-Chip) which is formed on an ultra-thin wafer that is handled with adhesive having tunable adhesion, according to some embodiments.

### DETAILED DESCRIPTION

Some embodiments describe an adhesive having tunable adhesion that provides immense flexibility and universality in terms of assembly, media designs, die handling as well as die release post dicing. In some embodiments, the adhesion properties of the adhesive can be dynamically tuned by changing properties of the adhesives. For example, when the temperature of an adhesive is above its glass transition temperature T_{g}, the adhesive holds a silicon wafer in place, and when the temperature of the adhesive is below T_{g}, the adhesive no longer holds the silicon wafer in place.

Transition temperature T_{g} is the temperature at which a material changes from one crystal state (e.g., allotrope) to another. Glass transition refers to reversible transition in amorphous materials (or in amorphous regions within semi-crystalline materials) from a hard (e.g., glass) and relatively brittle state into a molten or rubber-like state. An amorphous solid that exhibits a glass transition is called a glass. The glass-transition temperature T_{g} is generally lower than the melting temperature, Tₘ, of the crystalline state of the material. As such, by cooling the adhesive polymer to below its T_{g}, it becomes glassy, and loses adhesion, thus allowing an easy pick up of silicon wafer or die. The adhesive material regains its adhesion upon being thawed back to room temperature, in accordance with some embodiments. Thus, such adhesion is reversible and as such tunable, in accordance with some embodiments.

In some embodiments, the adhesion could potentially be changed globally, (e.g., across an entire adhesive media tray and/or post dicing), or it can be changed locally, (e.g., cool only an adhesive portion under the die(s) that are going to be picked). In some embodiments, in the die preparation area, a bonded-wafer processing technique can be used for holding and releasing ultra-thin dies post dicing. In some embodiments, bonded-wafer adhesives are washed off using water or solvent, thus the die can be released. In some embodiments, vacuum chuck technology (for die release post dicing) is used as media technology in assembly. The adhesive material with tunable adhesion of the various embodiments offers immense flexibility and universality in terms of assembly, media designs, die handling, as well as die release post dicing.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level. The term “scaling” may also refer to shrinking thickness of a silicon wafer. The terms “substantially,” “close,” “approximately,” “near,” and “about,” generally refer to being within +/−10% of a target value.

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left,” “right,” “front,” “back,” “bottom,” “over,” “under,” and the like in the description and in the claims, if any, are used for descriptive purposes and not necessarily for describing permanent relative positions.

For purposes of the embodiments, the transistors in various circuits, logic blocks, and dies are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, etc., may be used without departing from the scope of the disclosure.

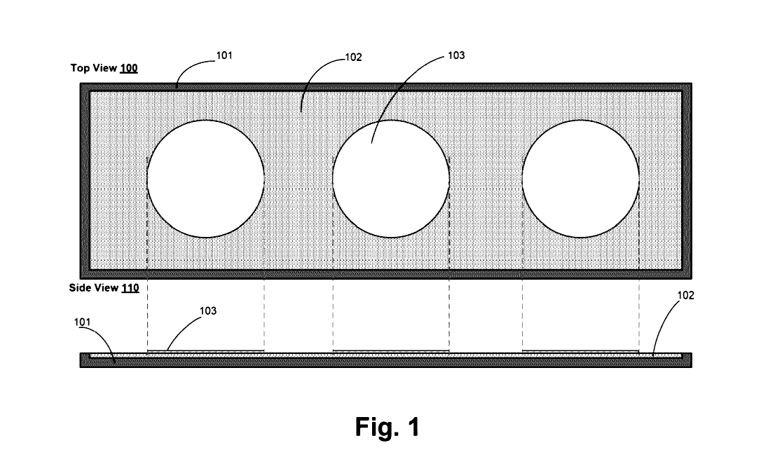

FIG. 1 illustrates top view 100 and its corresponding side view 110 of a wafer tray processed with adhesive having tunable adhesion, the wafer tray having one or more wafers, in accordance with some embodiments of the disclosure. Here, top view 100 and its side view 110 illustrate wafer tray 101, adhesive material 102, and wafers 103. In some embodiments, adhesive material 102 is deposited on wafer tray 101 to provide handling mechanisms for silicon wafers. Wafer tray 101 can be any wafer handling or carrying apparatus. In the various embodiments described here, wafer tray 101 is formed of thermal conducting material (e.g., metal).

In some embodiments, adhesion properties of adhesive material 102 can be tuned by changing properties of the adhesives. Here, adhesive material 102 can hold silicon wafer 102 in place on wafer tray 101 at room temperature, which is above the glass transition temperature, or T_{g} of adhesive material 102. In some embodiments, the adhesive properties can be changed or tuned by changing the temperature of adhesive material 102. In some embodiments, the adhesive properties can be changed or tuned dynamically (e.g., any time when it is desired to change the adhesive characteristics of adhesive material 102).

In some embodiments, adhesive material 102 is formed of at least one of: Thermoplastic elastomers; Polysulfide rubber; Elastolefin (e.g., a fiber composed of at least 95% by weight of macromolecules partially cross-linked, made of ethylene and at least one other olefin); Natural polyisoprene (or natural rubber); Synthetic polyisoprene (or synthetic rubber); Polybutadiene; Chloroprene; Polychloroprene; Neoprene; Baypren; Butyl Rubber; Styrene-butadiene; Nitrile rubber; or Saturated rubbers.

Thermoplastic elastomers (TPE) (or thermoplastic rubbers) are a class of copolymers or a physical mix of polymers (e.g., plastic, rubber, etc.) which comprise of materials with both thermoplastic and elastomeric properties. An elastomer is a polymer with viscoelasticity (i.e., having both viscosity and elasticity) and very weak inter-molecular forces, generally having low Young's modulus and high failure strain compared with other materials. As such, an elastomer is a material with a mechanical (or material) property that can undergo much more elastic deformation under stress than most materials and still return to its previous size without permanent deformation. Some types of TPEs include: Styrenic block copolymers (TPE-s), Polyolefin blends (TPE-o), Elastomeric alloys (TPE-v or TPV), Thermoplastic polyurethanes (TPU), Thermoplastic copolyester, and Thermoplastic polyamides.

Natural rubber generally comes from latex of Hevea brasiliensis, and is mainly poly-cis-isoprene containing traces of impurities like protein, dirt, etc. Synthetic rubber, on the other hand, is made by the polymerization of a variety of petroleum-based precursors called monomers. Examples of synthetic rubber include: Polyacrylate Rubber, Ethylene-acrylate Rubber, Polyester Urethane, Bromo Isobutylene Isoprene, Polybutadiene, Chloro Isobutylene Isoprene, Polychloroprene, Chlorosulphonated Polyethylene, Epichlorohydrin, Ethylene Propylene, Ethylene Propylene Diene Monomer, Polyether Urethane, Perfluorocarbon Rubber, Fluoronated Hydrocarbon, Fluoro Silicone, Fluorocarbon Rubber, Hydrogenated Nitrile Butadiene, Polyisoprene, Isobutylene Isoprene Butyl, Acrylonitrile Butadiene, Polyurethane, Styrene Butadiene, Styrene Ethylene Butylene Styrene Copolymer, Polysiloxane, Vinyl Methyl Silicone, Acrylonitrile Butadiene Carboxy Monomer, Styrene Butadiene Carboxy Monomer, Thermoplastic Polyether-ester, Styrene Butadiene Block Copolymer, Styrene Butadiene Carboxy Block Copolymer, etc.

Other materials that can be used for adhesive material 102 include: trans 1,4-polyisoprene gutta-percha; Synthetic polyisoprene (IR for isoprene rubber); Polybutadiene (BR for butadiene rubber); Chloroprene rubber (CR), polychloroprene, Neoprene, Baypren etc.; Butyl rubber (copolymer of isobutylene and isoprene, HR); Halogenated butyl rubbers (chloro butyl rubber: CIIR; bromo butyl rubber: BIIR); Styrene-butadiene Rubber (copolymer of styrene and butadiene, SBR); Nitrile rubber (copolymer of butadiene, and acrylonitrile, NBR), also called Buna N rubbers; Hydrogenated Nitrile Rubbers (HNBR) Therban and Zetpol (Unsaturated rubbers can also be cured by non-sulfur vulcanization if desired); Saturated rubbers that cannot be cured by sulfur vulcanization such as EPM (ethylene propylene rubber, a copolymer of ethylene and propylene) and EPDM rubber (ethylene propylene diene rubber, a terpolymer of ethylene, propylene and a diene-component); Epichlorohydrin rubber (ECO); Polyacrylic rubber (ACM, ABR); Silicone rubber (SI, Q, VMQ); Fluorosilicone Rubber (FVMQ); Fluoroelastomers (FKM, and FEPM) Viton, Tecnoflon, Fluorel, Aflas and Dai-El; Perfluoroelastomers (FFKM) Tecnoflon PFR, Kalrez, Chemraz, Perlast; Polyether block amides (PEBA); Chlorosulfonated polyethylene (CSM), (Hypalon); Ethylene-vinyl acetate (EVA), etc.

The above list of materials are not meant to be an exclusive list of adhesive materials with tunable adhesion properties. Other adhesive materials with tunable adhesion properties may be used for handling silicon wafer dies by forming a layer on thermally conductive wafer handling devices such as metal wafer trays. For example, adhesive materials with T_{g} in the range of −75° Celsius (C) to 0° C. can be used as adhesive material 102.

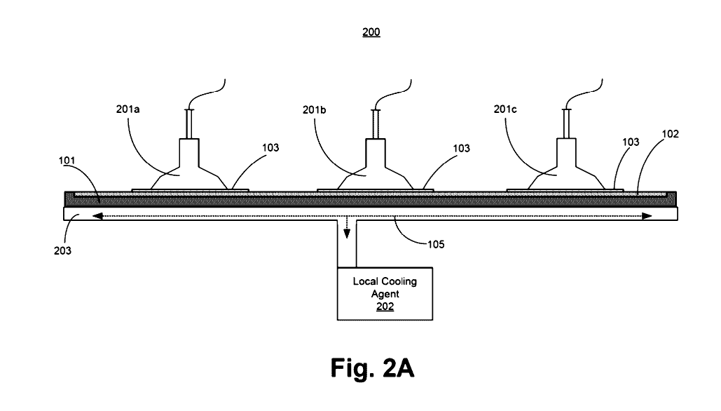

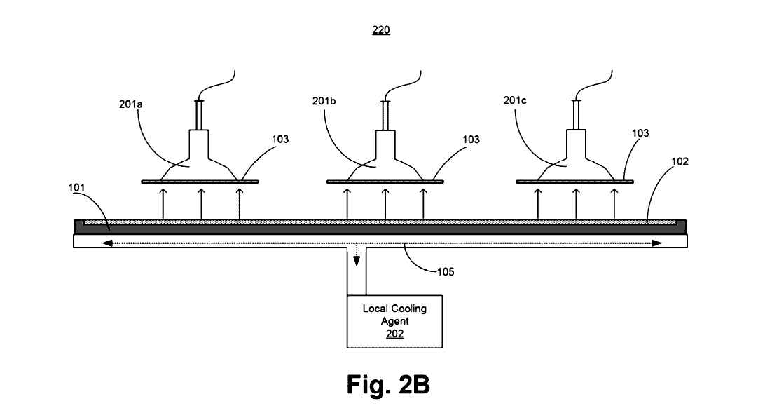

FIGS. 2A-B illustrate side views 200 and 220, respectively, of the wafer tray of FIG. 1 with apparatus to cool the adhesive for picking up the wafers off wafer tray 101, according to some embodiments of the disclosure. It is pointed out that those elements of FIGS. 2A-B having the same reference numbers (or names) as the elements of any other figure can operate or function in any manner similar to that described, but are not limited to such.

In some embodiments, a vacuum apparatus 201 is provided which is configured and operable to lift wafer 103 from wafer tray 101 when suction is created by vacuum apparatus 201. Here, three vacuum apparatuses 201a/b/c (which are collectively referred to as vacuum apparatus 201) are shown for each of wafers 103. So as not to obscure the embodiments, any of the three vacuum apparatuses is referred to as vacuum apparatus 201. In some embodiments, the surface area of vacuum apparatus 201, which is to be in contact with wafer 103, is less than the surface area of wafer 103. In some embodiments, the surface area of vacuum apparatus 201, which is to be in contact with wafer 103, is substantially equal to the surface area of wafer 103. In some embodiments, the surface area of vacuum apparatus 201, which is to be in contact with wafer 103, is greater than the surface area of wafer 103.

In some embodiments, Cooling Agent 202 is provided to cool the layer of adhesive material 102 via conduit 203. In some embodiments, conduit 203 extends along the entire length of the backside surface of tray 101. In some embodiments, conduit 203 loops around as coils along the backside surface of wafer tray 101 to cover the entire tray area. In some embodiments, Cooling Agent 202 cycles cooling material, such as liquid nitrogen (LN₂), through conduit 203 to quickly cool the temperature of wafer tray 101, and thus the temperature of adhesive material 102 to be below T_{g} of adhesive material 102.

In some embodiments, cooling material flows through conduit 203 such that the entire backside of wafer tray 103 is cooled down, and as such, adhesive material 102 is also cooled down below T_{g}. FIG. 2B illustrates the case when vacuum apparatuses 201a/b/c lift off wafers 103 without any damage to the wafers, after adhesive material 102 is cooled down below T_{g}.

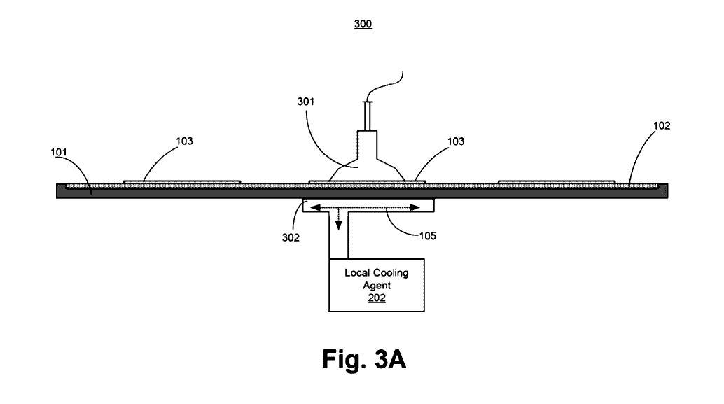

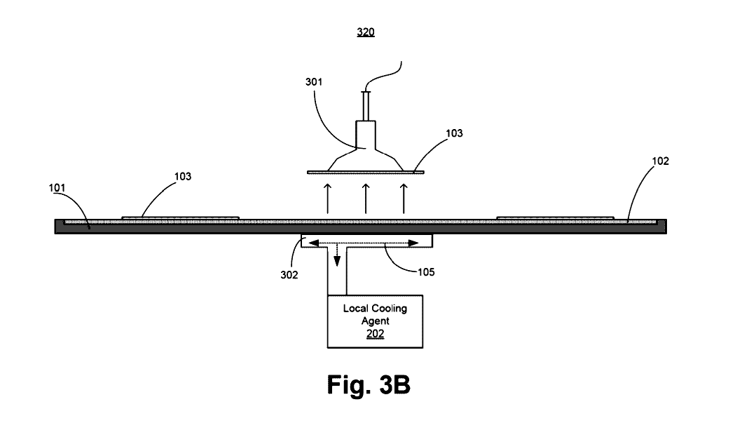

FIGS. 3A-B illustrate side views 300 and 320, respectively of the wafer tray of FIG. 1 with apparatus to locally cool a portion of the adhesive for picking up one wafer off wafer tray 101, according to some embodiments of the disclosure. It is pointed out that those elements of FIGS. 3A-B having the same reference numbers (or names) as the elements of any other figure can operate or function in any manner similar to that described, but are not limited to such.

Compared to the embodiments of FIGS. 2A-B, here, a portion of adhesive material 102 is cooled instead of the entire adhesive material 102. In some embodiments, when one wafer is desired to be lifted off by one vacuum apparatus 301 (e.g., same as 201b), conduit 302 (e.g., a smaller conduit than conduit 202) is used to locally cool wafer tray 101 underneath the surface area of wafer 103 which is to be lifted off.

In some embodiments, conduit 302 loops around in coils to cover the surface area of wafer 103. In some embodiments, conduit 302 covers an entire surface area of wafer 103 as one conduit. In some embodiments, cooling material flows through conduit 302 such that the entire surface area of wafer 103 is cooled down, and as such, the adhesive material 102 is also cooled down below T_{g}. FIG. 3B illustrates the case when vacuum apparatus 301 lifts off wafer 103 without any damage to the wafer, after adhesive material 102 is cooled down below T_{g}. Here, the remaining wafers remain intact with adhesive material 102 because the adhesion properties for adhesive material 102 in contact with the wafers does not change.

While the embodiment(s) of FIGS. 3A-B are illustrated with reference to local cooling of one wafer to lift off one wafer, two or more wafer areas may be locally cooled and two or more vacuum apparatuses can be used to lift off those wafers whose associated adhesive materials are cooled (e.g., below T_{g}).

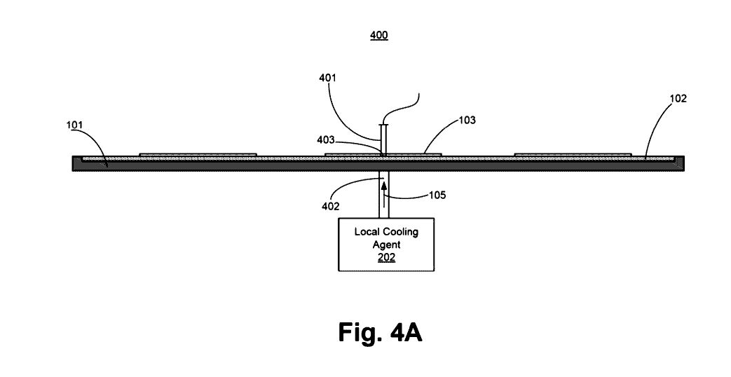

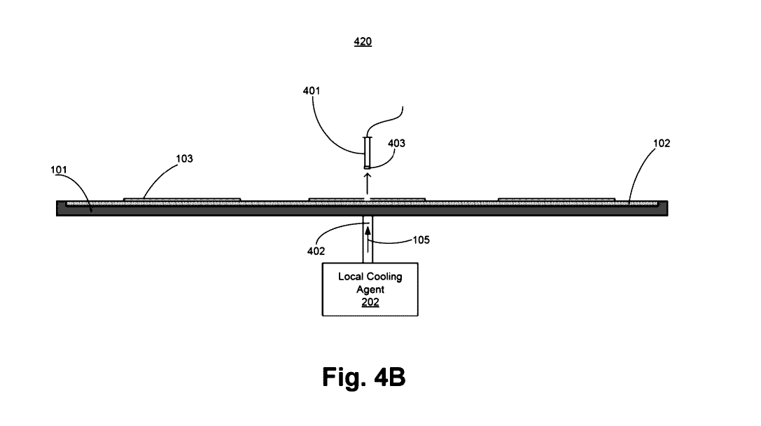

FIGS. 4A-B illustrate side views 400 and 420, respectively, of the wafer tray of FIG. 1 with apparatus to locally cool a portion of the adhesive for picking up one die from a wafer off the wafer tray, according to some embodiments of the disclosure. It is pointed out that those elements of FIGS. 4A-B having the same reference numbers (or names) as the elements of any other figure can operate or function in any manner similar to that described, but are not limited to such.

In some embodiments, after wafer 103 is diced and sliced into dies (which is part of the process of manufacturing and packaging of dies), one or more individual dies can be lifted off from wafer tray 101 without causing other dies of the wafer to shift from their position. With reference to FIG. 3A, die 403 of wafer 103 is desired to be lifted off. In some embodiments, vacuum apparatus 401 is provided which is operable to lift one die at a time from wafer 103 without causing other dies of wafer 103 to shift their positions.

In some embodiments, a conduit is engineered (such as conduit 402) to locally cool only a surface area of wafer tray 101 which covers a surface area of die 403. As such, adhesive material 102, which is under die 403, is cooled through cooling material provided by Cooling Agent 202 while the rest of the area of wafer tray 101 remains at previous temperature (e.g., room temperature at which adhesive material 102 exhibits adhesive properties). As such, the rest of the dies of wafer 103 and other wafers on wafer tray 101 remain attached to adhesive material 102 because adhesive properties for the rest of adhesive material 102 on wafer tray 101 are not changed.

FIG. 4B illustrates the case when vacuum apparatus 401 lifts off die 403 without any damage to die 403, after adhesive material 102 under die 403 is cooled (e.g., below T_{g}). Here, the remaining wafers and dies remain intact with adhesive material 102 because the adhesion properties for adhesive material 102 in contact with the wafers does not change.

While the embodiment(s) of FIGS. 4A-B are illustrated with reference to local cooling of one die to lift off from one wafer, two or more dies of the same or different wafers can be locally cooled and two or more vacuum apparatuses can be used to lift off those dies whose associated adhesive materials are cooled.

While the embodiments are described with reference to a wafer or die being handled by adhesive 102, the embodiments are not limited to such. For example, in some embodiments, the target object being handled is/are thin package(s) with small form factors generally (e.g., less than 20×20 mm and thickness less than 1 mm total). In some embodiments, a tape for handling the thin package(s) has adhesive material 102. In some embodiments, the tape can be used in the assembly flow for handling and shipping of small form factor packages using the adhesive material 102 and by tuning its adhesive properties dynamically as needed. As such, the requisite for expensive media tray designs and materials may be reduced in accordance with some embodiments.

In some embodiments, an apparatus is provides which comprises a tape, a chip package, and a cooling agent. In some embodiments, the tape has an adhesive layer (e.g., layer 102) which is to be in direct contact with the chip package for handling the chip package. The chip package may have one or more dies encased in it, in accordance with some embodiments. In some embodiments, the chip package may be an empty package which is to be used to encase one or more dies. In some embodiments, the chip package is attached to the tape via the adhesive layer. In some embodiments, the cooling agent is provided which is operable to cool at least a portion of the adhesive layer of the tape below its glass transition temperature (T_{g}) such that the chip package can be lifted off the tape.

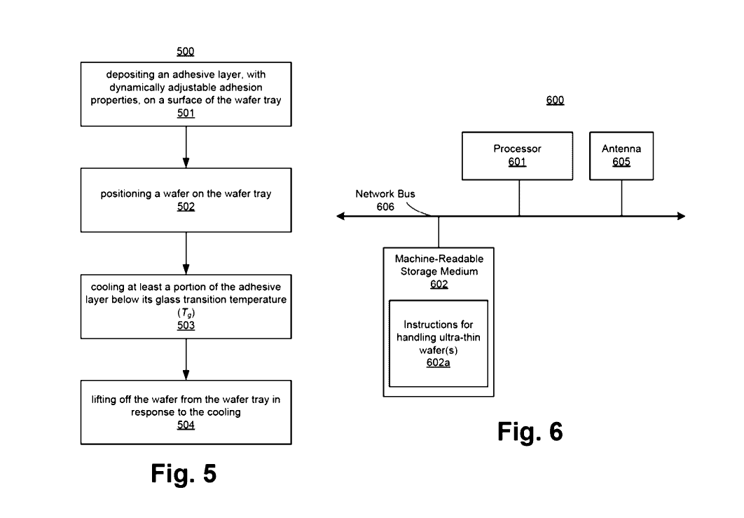

FIG. 5 illustrates flowchart 500 of a method for handling ultra-thin wafer(s), according to some embodiments of the disclosure. It is pointed out that those elements of FIG. 5 having the same reference numbers (or names) as the elements of any other figure can operate or function in any manner similar to that described, but are not limited to such.

Although the blocks in the flowchart with reference to FIG. 5 are shown in a particular order, the order of the actions can be modified. Thus, the illustrated embodiments can be performed in a different order, and some actions/blocks may be performed in parallel. Some of the blocks and/or operations listed in FIG. 5 are optional in accordance with certain embodiments. The numbering of the blocks presented is for the sake of clarity and is not intended to prescribe an order of operations in which the various blocks must occur. Additionally, operations from the various flows may be utilized in a variety of combinations.

At block 501, adhesive layer 102 is deposited on wafer tray 101. Any known suitable method(s) can be used for applying adhesive layer 102 on wafer tray 101. At block 502, wafers 103 are positioned on wafer tray 101 over adhesive layer 102. While the embodiments are described with reference to wafer handling on a wafer tray 101, adhesive material 102 can be used for handling any other thin material or device (e.g., packaging material which is to be applied on the dies of the wafer, etc.). As described with reference to various embodiments, adhesive material 102 has adhesion properties at room temperature and can lose its adhesive properties when cooled down below its T_{g}.

At block 503, Cooling Agent 202 cools at least a portion of adhesive layer 102 to below its T_{g}. As such, adhesive layer 102 becomes like a glass (i.e., smooth) and loses friction with wafer 103. At block 504, wafer 103 is then lifted off from wafer tray 101 using vacuum apparatus 201. In other embodiments, local cooling can be applied as discussed with reference to FIGS. 3-4, and a wafer or a die of a wafer can be lifted off. In some embodiments, a similar flowchart can be used for handling thin packages using a tape having adhesive material 102.

FIG. 6 illustrates system 600 having a machine-readable storage media having instructions stored thereon to perform one or more operations of the flowchart of FIG. 5, in accordance with some embodiments of the disclosure. It is pointed out that those elements of FIG. 6 having the same reference numbers (or names) as the elements of any other figure can operate or function in any manner similar to that described, but are not limited to such.

In some embodiments, system 600 comprises Processor 601 (e.g., a Digital Signal Processor (DSP), an Application Specific Integrated Circuit (ASIC), a general purpose Central Processing Unit (CPU), or a low power logic implementing a simple finite state machine to perform one or more operations of flowchart 500), Machine-Readable Storage Medium 602 (also referred to as tangible machine readable medium), Antenna 605, and Network Bus 606.

In some embodiments, the various logic blocks of system 600 are coupled together via Network Bus 606. Any suitable protocol may be used to implement Network Bus 606. In some embodiments, Machine-Readable Storage Medium 602 includes Instructions 602a (also referred to as the program software code/instructions) for requesting and accepting a new power supply (e.g., new voltage and/or current) as described with reference to various embodiments and flowchart. Here, Instructions 602a are one or more instructions of flowchart 500 as described with reference to FIG. 5.

Program software code/instructions 602a, executed to implement embodiments of the disclosed subject matter, may be implemented as part of an operating system or a specific application, component, program, object, module, routine, or other sequence of instructions or organization of sequences of instructions referred to as “program software code/instructions,” “operating system program software code/instructions,” “application program software code/instructions,” or simply “software” or firmware embedded in processor. In some embodiments, the program software code/instructions are associated with flowchart 500, as described with reference to FIG. 5.

In some embodiments, the program software code/instructions 602a associated with flowchart 500 are stored in a computer executable storage medium 602 and executed by Processor 601. Here, computer executable storage medium 602 is a tangible machine readable medium that can be used to store program software code/instructions and data that, when executed by a computing device, causes one or more processors (e.g., Processor 601) to perform a method(s) as may be recited in one or more accompanying claims directed to the disclosed subject matter.

The tangible machine readable medium 602 may include storage of the executable software program code/instructions 602a and data in various tangible locations, including for example ROM, volatile RAM, non-volatile memory and/or cache and/or other tangible memory as referenced in the present application. Portions of this program software code/instructions 602a and/or data may be stored in any one of these storage and memory devices. Further, the program software code/instructions can be obtained from other storage, including, e.g., through centralized servers or peer to peer networks and the like, including the Internet. Different portions of the software program code/instructions and data can be obtained at different times and in different communication sessions or in the same communication session.

The software program code/instructions 602a (associated with one or more operations of flowchart 500 as described with reference to FIG. 5 and other embodiments) and data can be obtained in their entirety prior to the execution of a respective software program or application by the computing device. Alternatively, portions of the software program code/instructions 602a and data can be obtained dynamically, e.g., just in time, when needed for execution. Alternatively, some combination of these ways of obtaining the software program code/instructions 602a and data may occur, e.g., for different applications, components, programs, objects, modules, routines or other sequences of instructions or organization of sequences of instructions, by way of example. Thus, it is not required that the data and instructions be on a tangible machine readable medium in entirety at a particular instance of time.

Examples of tangible computer-readable media 602 include but are not limited to recordable and non-recordable type media such as volatile and non-volatile memory devices, read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs), etc.), among others. The software program code/instructions may be temporarily stored in digital tangible communication links while implementing electrical, optical, acoustical or other forms of propagating signals, such as carrier waves, infrared signals, digital signals, etc. through such tangible communication links.

In general, tangible machine readable medium 602 includes any tangible mechanism that provides (i.e., stores and/or transmits in digital form, e.g., data packets) information in a form accessible by a machine (i.e., a computing device), which may be included, e.g., in a communication device, a computing device, a network device, a personal digital assistant, a manufacturing tool, a mobile communication device, whether or not able to download and run applications and subsidized applications from the communication network, such as the Internet, e.g., an iPhone®, Galaxy®, Blackberry® Droid®, or the like, or any other device including a computing device. In one embodiment, processor-based system is in a form of or included within a PDA (personal digital assistant), a cellular phone, a notebook computer, a tablet, a game console, a set top box, an embedded system, a TV (television), a personal desktop computer, etc. Alternatively, the traditional communication applications and subsidized application(s) may be used in some embodiments of the disclosed subject matter.

Here, Antenna 605 can be any antenna. For example, in some embodiments, Antenna 605 may comprise one or more directional or omnidirectional antennas, including monopole antennas, dipole antennas, loop antennas, patch antennas, microstrip antennas, coplanar wave antennas, or other types of antennas suitable for transmission of RF (Radio Frequency) signals. In some multiple-input-multiple-output (MIMO) embodiments, Antenna(s) 505 are separated to take advantage of spatial diversity.

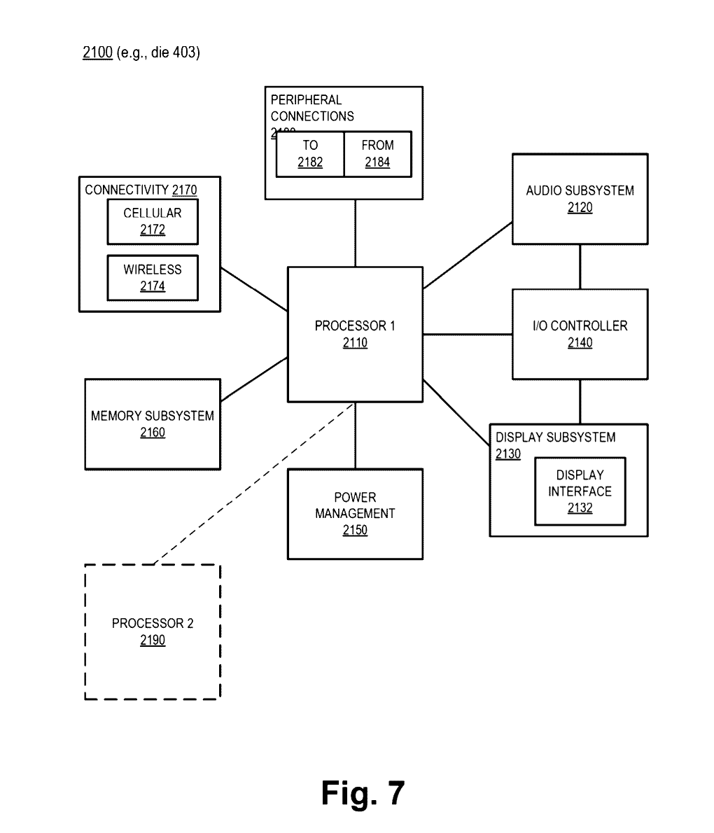

FIG. 7 illustrates a smart device or a computer system or a SoC (System-on-Chip) 2100 (e.g., die 403 of FIG. 4A-B) which is formed on an ultra-thin wafer 103 that is handled with adhesive 102 having tunable adhesion, according to some embodiments. It is pointed out that those elements of FIG. 7 having the same reference numbers (or names) as the elements of any other figure can operate or function in any manner similar to that described, but are not limited to such.

FIG. 7 illustrates a block diagram of an embodiment of a mobile device in which flat surface interface connectors could be used. In some embodiments, computing device 2100 represents a mobile computing device, such as a computing tablet, a mobile phone or smart-phone, a wireless-enabled e-reader, or other wireless mobile device. It will be understood that certain components are shown generally, and not all components of such a device are shown in computing device 2100.

In some embodiments, computing device 2100 includes a first processor 2110 (e.g., part of die 403). The various embodiments of the present disclosure may also comprise a network interface within 2170 such as a wireless interface so that a system embodiment may be incorporated into a wireless device, for example, cell phone or personal digital assistant.

In one embodiment, processor 2110 (and/or processor 2190, e.g., part of die 403) can include one or more physical devices, such as microprocessors, application processors, microcontrollers, programmable logic devices, or other processing means. The processing operations performed by processor 2110 include the execution of an operating platform or operating system on which applications and/or device functions are executed. The processing operations include operations related to I/O (input/output) with a human user or with other devices, operations related to power management, and/or operations related to connecting the computing device 2100 to another device. The processing operations may also include operations related to audio I/O and/or display I/O.

In one embodiment, computing device 2100 includes audio subsystem 2120, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 2100, or connected to the computing device 2100. In one embodiment, a user interacts with the computing device 2100 by providing audio commands that are received and processed by processor 2110.

Display subsystem 2130 represents hardware (e.g., display devices) and software (e.g., drivers) components that provide a visual and/or tactile display for a user to interact with the computing device 2100. Display subsystem 2130 includes display interface 2132, which includes the particular screen or hardware device used to provide a display to a user. In one embodiment, display interface 2132 includes logic separate from processor 2110 to perform at least some processing related to the display. In one embodiment, display subsystem 2130 includes a touch screen (or touch pad) device that provides both output and input to a user.

I/O controller 2140 represents hardware devices and software components related to interaction with a user. I/O controller 2140 is operable to manage hardware that is part of audio subsystem 2120 and/or display subsystem 2130. Additionally, I/O controller 2140 illustrates a connection point for additional devices that connect to computing device 2100 through which a user might interact with the system. For example, devices that can be attached to the computing device 2100 might include microphone devices, speaker or stereo systems, video systems or other display devices, keyboard or keypad devices, or other I/O devices for use with specific applications such as card readers or other devices.

As mentioned above, I/O controller 2140 can interact with audio subsystem 2120 and/or display subsystem 2130. For example, input through a microphone or other audio device can provide input or commands for one or more applications or functions of the computing device 2100. Additionally, audio output can be provided instead of, or in addition to display output. In another example, if display subsystem 2130 includes a touch screen, the display device also acts as an input device, which can be at least partially managed by I/O controller 2140. There can also be additional buttons or switches on the computing device 2100 to provide I/O functions managed by I/O controller 2140.

In one embodiment, I/O controller 2140 manages devices such as accelerometers, cameras, light sensors or other environmental sensors, or other hardware that can be included in the computing device 2100. The input can be part of direct user interaction, as well as providing environmental input to the system to influence its operations (such as filtering for noise, adjusting displays for brightness detection, applying a flash for a camera, or other features).

In one embodiment, computing device 2100 includes power management 2150 that manages battery power usage, charging of the battery, and features related to power saving operation. Memory subsystem 2160 includes memory devices for storing information in computing device 2100. Memory can include nonvolatile (state does not change if power to the memory device is interrupted) and/or volatile (state is indeterminate if power to the memory device is interrupted) memory devices. Memory subsystem 2160 can store application data, user data, music, photos, documents, or other data, as well as system data (whether long-term or temporary) related to the execution of the applications and functions of the computing device 2100.

Elements of embodiments are also provided as a machine-readable medium (e.g., memory 2160) for storing the computer-executable instructions. The machine-readable medium (e.g., memory 2160) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 2170 includes hardware devices (e.g., wireless and/or wired connectors and communication hardware) and software components (e.g., drivers, protocol stacks) to enable the computing device 2100 to communicate with external devices. The computing device 2100 could be separate devices, such as other computing devices, wireless access points or base stations, as well as peripherals such as headsets, printers, or other devices.

Connectivity 2170 can include multiple different types of connectivity. To generalize, the computing device 2100 is illustrated with cellular connectivity 2172 and wireless connectivity 2174. Cellular connectivity 2172 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 2174 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 2180 include hardware interfaces and connectors, as well as software components (e.g., drivers, protocol stacks) to make peripheral connections. It will be understood that the computing device 2100 could both be a peripheral device (“to” 2182) to other computing devices, as well as have peripheral devices (“from” 2184) connected to it. The computing device 2100 commonly has a “docking” connector to connect to other computing devices for purposes such as managing (e.g., downloading and/or uploading, changing, synchronizing) content on computing device 2100. Additionally, a docking connector can allow computing device 2100 to connect to certain peripherals that allow the computing device 2100 to control content output, for example, to audiovisual or other systems.

In addition to a proprietary docking connector or other proprietary connection hardware, the computing device 2100 can make peripheral connections 1680 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

For example, an apparatus is provided which comprises: a wafer tray having an adhesive layer, with dynamically adjustable adhesion properties, deposited on a surface of the wafer tray; a wafer positioned on the wafer tray; and a cooling agent which is operable to cool at least a portion of the adhesive layer below its glass transition temperature (T_{g}) such that the wafer can be lifted off the wafer tray. In some embodiments, the adhesive layer is formed of a material having T_{g} below room temperature.

In some embodiments, the adhesive layer is formed of at least one of: Thermoplastic elastomers; Polysulfide rubber; Elastolefin; Natural polyisoprene; Synthetic polyisoprene; Polybutadiene; Chloroprene; Polychloroprene; Neoprene; Baypren; Butyl Rubber; Styrene-butadiene; Nitrile rubber; or Saturated rubbers. \

In some embodiments, the wafer tray is a metal tray or of a material that conducts heat. In some embodiments, the cooling agent is operable to cool via liquid nitrogen. In some embodiments, the wafer has a thickness of less than 50 μm. In some embodiments, the cooling agent is operable to cool at least a portion of the adhesive layer such that a die of the wafer is lifted while other dies stick to the adhesive layer. In some embodiments, the apparatus comprises a vacuum machine to pick up the wafer.

In another example, a method is provided which comprises: depositing an adhesive layer, with dynamically adjustable adhesion properties, on a surface of the wafer tray; positioning a wafer on the wafer tray; cooling at least a portion of the adhesive layer below its glass transition temperature (T_{g}); and lifting off the wafer from the wafer tray in response to the cooling. In some embodiments, cooling the portion of the adhesive layer comprises passing liquid nitrogen near a bottom surface of the wafer tray. In some embodiments, the portion of the adhesive layer covers an entire wafer surface area. In some embodiments, the portion of the adhesive layer covers a surface area of a die of the wafer.

In some embodiments, the adhesive layer is formed of a material having T_{g} below room temperature. In some embodiments, the adhesive layer is formed of at least one of: Thermoplastic elastomers; Polysulfide rubber; Elastolefin; Natural polyisoprene; Synthetic polyisoprene; Polybutadiene; Chloroprene; Polychloroprene; Neoprene; Baypren; Butyl Rubber; Styrene-butadiene; Nitrile rubber; or Saturated rubbers. In some embodiments, the wafer has a thickness of less than 25 μm.

In another example, a machine-readable storage media is provided having machine readable instructions stored thereon, that when executed, cause one of more machines to perform an operation comprising: deposit an adhesive layer, with dynamically adjustable adhesion properties, on a surface of the wafer tray; position a wafer on the wafer tray; cool at least a portion of the adhesive layer below its glass transition temperature (T_{g}); and lift off the wafer from the wafer tray in response to the cooling. In some embodiments, the operation to cool the portion of the adhesive layer comprises an operation to pass liquid nitrogen near a bottom surface of the wafer tray.

In some embodiments, the adhesive layer is formed of a material having T_{g} below room temperature. In some embodiments, the adhesive layer is formed of at least one of: Thermoplastic elastomers; Polysulfide rubber; Elastolefin; Natural polyisoprene; Synthetic polyisoprene; Polybutadiene; Chloroprene; Polychloroprene; Neoprene; Baypren; Butyl Rubber; Styrene-butadiene; Nitrile rubber; or Saturated rubbers.

In another example, an apparatus is provided which comprises: a tape having an adhesive layer, the adhesive layer having dynamically adjustable adhesion properties; a chip package to be attached to the tape via the adhesive layer; and a cooling agent which is operable to cool at least a portion of the adhesive layer below its glass transition temperature (T_{g}) such that the chip package can be lifted off the tape. In some embodiments, the adhesive layer is formed of a material having T_{g} below room temperature. In some embodiments, the chip package encloses one or more dies.

In some embodiments, the adhesive layer is formed of at least one of: Thermoplastic elastomers; Polysulfide rubber; Elastolefin; Natural polyisoprene; Synthetic polyisoprene; Polybutadiene; Chloroprene; Polychloroprene; Neoprene; Baypren; Butyl Rubber; Styrene-butadiene; Nitrile rubber; or Saturated rubbers.

In some embodiments, the cooling agent is operable to cool via liquid nitrogen. In some embodiments, the cooling agent is operable to cool at least a portion of the adhesive layer such that at least one chip package can be lifted while other chip packages remain attached to the adhesive layer. In some embodiments, the apparatus a vacuum machine to pick up the chip package.

In another example, an apparatus is provided which comprises: means for depositing an adhesive layer, with dynamically adjustable adhesion properties, on a surface of the wafer tray; means for positioning a wafer on the wafer tray; means for cooling at least a portion of the adhesive layer below its glass transition temperature (T_{g}); and means for lifting off the wafer from the wafer tray in response to the cooling. In some embodiments, the means for cooling the portion of the adhesive layer comprises means for passing liquid nitrogen near a bottom surface of the wafer tray.

In some embodiments, the portion of the adhesive layer covers an entire wafer surface area. In some embodiments, the portion of the adhesive layer covers a surface area of a die of the wafer. In some embodiments, the adhesive layer is formed of a material having T_{g} below room temperature. In some embodiments, the adhesive layer is formed of at least one of: Thermoplastic elastomers; Polysulfide rubber; Elastolefin; Natural polyisoprene; Synthetic polyisoprene; Polybutadiene; Chloroprene; Polychloroprene; Neoprene; Baypren; Butyl Rubber; Styrene-butadiene; Nitrile rubber; or Saturated rubbers. In some embodiments, the wafer has a thickness of less than 25 μm.

In another example, a method is provided which comprises: depositing an adhesive layer, with dynamically adjustable adhesion properties, on a tape; attaching the tape to a chip package; cooling at least a portion of the adhesive layer below its glass transition temperature (T_{g}); and lifting off the chip package in response to the cooling. In some embodiments, the adhesive layer is formed of a material having T_{g} below room temperature.

In some embodiments, the method comprises: enclosing one or more dies in the chip package. In some embodiments, the adhesive layer is formed of at least one of: Thermoplastic elastomers; Polysulfide rubber; Elastolefin; Natural polyisoprene; Synthetic polyisoprene; Polybutadiene; Chloroprene; Polychloroprene; Neoprene; Baypren; Butyl Rubber; Styrene-butadiene; Nitrile rubber; or Saturated rubbers.

In some embodiments, the cooling agent is operable to cool via liquid nitrogen. In some embodiments, the method comprises: cooling at least a portion of the adhesive layer such that at least one chip package can be lifted while other chip packages remain attached to the adhesive layer. In some embodiments, the method comprises picking up the chip package using a vacuum machine.

In another example, a machine-readable storage media is provided having machine readable instructions stored thereon, that when executed, cause one of more machines to perform a method according to the method discussed above.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. An apparatus comprising:
a wafer tray having an adhesive layer, with dynamically adjustable adhesion properties, deposited on a surface of the wafer tray;
a wafer positioned on the wafer tray; and
a cooling agent which is operable to cool at least a portion of the adhesive layer below its glass transition temperature (T_{g}) such that the wafer can be lifted off the wafer tray.

2. The apparatus of claim 1, wherein the adhesive layer is formed of a material having T_{g} below room temperature.

3. The apparatus of claim 1, wherein the adhesive layer is formed of at least one of:
Thermoplastic elastomers;
Polysulfide rubber;
Elastolefin;
Natural polyisoprene;
Synthetic polyisoprene;
Polybutadiene;
Chloroprene;
Polychloroprene;
Neoprene;
Baypren;
Butyl Rubber;
Styrene-butadiene;
Nitrile rubber; or
Saturated rubbers.

4. The apparatus of claim 1, wherein the wafer tray is a metal tray or of a material that conducts heat.

5. The apparatus of claim 1, wherein the cooling agent is operable to cool via liquid nitrogen.

6. The apparatus of claim 1, wherein the wafer has a thickness of less than 50 μm.

7. The apparatus of claim 1, wherein cooling agent is operable to cool at least a portion of the adhesive layer such that a die of the wafer is lifted while other dies stick to the adhesive layer.

8. The apparatus of claim 1 comprises a vacuum machine to pick up the wafer.

9. A method comprising:
depositing an adhesive layer, with dynamically adjustable adhesion properties, on a surface of the wafer tray;
positioning a wafer on the wafer tray;
cooling at least a portion of the adhesive layer below its glass transition temperature (T_{g}); and
lifting off the wafer from the wafer tray in response to the cooling.

10. The method of claim 9, wherein cooling the portion of the adhesive layer comprises passing liquid nitrogen near a bottom surface of the wafer tray.

11. The method of claim 9, wherein the portion of the adhesive layer covers an entire wafer surface area.

12. The method of claim 9, wherein the portion of the adhesive layer covers a surface area of a die of the wafer.

13. The method of claim 9, wherein the adhesive layer is formed of a material having T_{g} below room temperature.

14. The method of claim 9, wherein the adhesive layer is formed of at least one of:
Thermoplastic elastomers;
Polysulfide rubber;
Elastolefin;
Natural polyisoprene;
Synthetic polyisoprene;
Polybutadiene;
Chloroprene;
Polychloroprene;
Neoprene;
Baypren;
Butyl Rubber;
Styrene-butadiene;
Nitrile rubber; or
Saturated rubbers.

15. The method of claim 9, wherein the wafer has a thickness of less than 25 μm.

16. Machine-readable storage media having machine readable instructions stored thereon, that when executed, cause one of more machines to perform an operation comprising:
deposit an adhesive layer, with dynamically adjustable adhesion properties, on a surface of the wafer tray;
position a wafer on the wafer tray;
cool at least a portion of the adhesive layer below its glass transition temperature (T_{g}); and
lift off the wafer from the wafer tray in response to the cooling.

17. The machine-readable storage media of claim 16, wherein the operation to cool the portion of the adhesive layer comprises an operation to pass liquid nitrogen near a bottom surface of the wafer tray.

18. The machine-readable storage media of claim 16, wherein the adhesive layer is formed of a material having T_{g} below room temperature.

19. The machine-readable storage media of claim 16, wherein the adhesive layer is formed of at least one of:
Thermoplastic elastomers;
Polysulfide rubber;
Elastolefin;
Natural polyisoprene;
Synthetic polyisoprene;
Polybutadiene;
Chloroprene;
Polychloroprene;
Neoprene;
Baypren;
Butyl Rubber;
Styrene-butadiene;
Nitrile rubber; or
Saturated rubbers.

20. An apparatus comprising:
a tape having an adhesive layer, the adhesive layer having dynamically adjustable adhesion properties;
a chip package to be attached to the tape via the adhesive layer; and
a cooling agent which is operable to cool at least a portion of the adhesive layer below its glass transition temperature (T_{g}) such that the chip package can be lifted off the tape.

21. The apparatus of claim 20, wherein the adhesive layer is formed of a material having T_{g} below room temperature.

22. The apparatus of claim 20, wherein the chip package encloses one or more dies.
